(19) United States
(12) Patent Application Publication
(10) Pub. No.: US 2026/0175248 A1
(43) Pub. Date: Jun. 25, 2026

(54) HOME PORT AND APPARATUS FOR PROCESSING SUBSTRATE WITH THE SAME

(71) Applicant: SEMES CO., LTD., Cheonan-si (KR)

(72) Inventors: Dae Sung KIM, Suwon-si (KR); Jae Ho LEE, Cheonan-si (KR); Nak Hyun SONG, Cheonan-si (KR); Jong Gu LEE, Sangju-si (KR); Jae Ho YOO, Seoul (KR)

(21) Appl. No.: 19/369,504

(22) Filed: Oct. 27, 2025

(30) Foreign Application Priority Data
Dec. 24, 2024 (KR) 10-2024-0194927

(51) Int. Cl. B05B 15/555; F26B 5/12; G03F 7/30

(52) U.S. Cl. CPC B05B 15/555; F26B 5/12; G03F 7/30

(57) ABSTRACT

In the present disclosure, provided are a home port and an apparatus for processing a substrate, the home port including a housing including a receiving space for receiving a lower portion of a nozzle, a cleaning liquid supply unit for supplying a cleaning liquid for cleaning the nozzle to the receiving space, a suction unit for suctioning the cleaning liquid or air from the receiving space, and a drain unit for draining a cleaning liquid having overflowed from the receiving space and a cleaning liquid suctioned through the suction unit to the outside of the housing.

### CROSS-REFERENCE TO RELATED APPLICATION(S)

This application claims the benefit of a priority to Korean Patent Application No. 10-2024-0194927 filed on Dec. 24, 2024 in the Korean Intellectual Property Office, the entire disclosure of which is incorporated herein by reference for all purposes.

### BACKGROUND

The present disclosure relates to a home port and an apparatus for processing a substrate with the same.

A photolithography process, in a semiconductor manufacturing process, is a process of forming a desired pattern on a wafer. The photolithography process is performed using an apparatus for processing a substrate, sequentially performing coating, exposure, and development processes, and such an apparatus for processing a substrate typically includes a home port in which a nozzle is held.

The nozzle periodically discharges a liquid from the home port to prevent contamination of the liquid that may occur when the liquid stagnates within the nozzle for a long period of time.

However, apart from the nozzle discharging the liquid on its own, there may be a problem in that when the nozzle in the home port is not cleaned or dried, contaminants attached to a surface of the nozzle may not be removed, which could cause defects in subsequent processes.

### SUMMARY

An aspect of the present disclosure is to provide a home port and an apparatus for processing a substrate including the same, which can reduce a defect rate of a process by efficiently performing cleaning and drying processing of a nozzle for processing a substrate.

An aspect of the present disclosure is to provide a home port and an apparatus for processing a substrate including the same, which can separate contaminants from a nozzle by supplying cleaning liquid to a receiving space for receiving a lower portion of the nozzle, suction the separated contaminants together with the cleaning liquid, and then perform drying processing of the nozzle all at once.

The objects of the present disclosure are not limited to the above-described scope. Those skilled in the art will have no difficulty understanding the additional objects of the present disclosure from the overall content of the present specification.

In order to achieve the above-described purpose, an aspect of the present disclosure is to provide a home port and an apparatus for processing a substrate including the same as follows.

According to an aspect of the present disclosure, a home port is provided, the home port including a housing including a receiving space for receiving a lower portion of a nozzle, a cleaning liquid supply unit for supplying a cleaning liquid for cleaning the nozzle to the receiving space, a suction unit for suctioning the cleaning liquid or air from the receiving space, and a drain unit for draining a cleaning liquid having overflowed from the receiving space and a cleaning liquid suctioned through the suction unit to the outside of the housing.

According to an aspect of the present disclosure, a home port is provided, the home port including a housing including a receiving space for receiving a lower portion of a nozzle, a cleaning liquid supply path installed inside the housing and supplying a cleaning liquid to the receiving space, a suction path installed inside the housing and suctioning the cleaning fluid from the receiving space, and an ejector installed in the suction path, and controlling pressure within the suction path.

According to an aspect of the present disclosure, an apparatus for processing a substrate is provided, in the apparatus for processing a substrate including a support unit for supporting a substrate, a liquid supply unit including a nozzle for discharging a processing liquid onto a substrate supported by the support unit, and a home port located to be spaced apart from the support unit, and in which the nozzle is held, wherein the home port includes a housing including a receiving space in which a portion of the nozzle is received, a cleaning liquid supply unit for supplying a cleaning liquid for cleaning the nozzle to the receiving space, a suction unit for suctioning the cleaning liquid or air from the receiving space, and a drain unit for draining a cleaning liquid having overflowed from the receiving space and a cleaning liquid suctioned through the suction unit to the outside of the housing.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 schematically illustrates an apparatus for processing a substrate according to an embodiment of the present disclosure;

FIG. 2 illustrates processing a substrate with a nozzle of an apparatus for processing a substrate according to an embodiment of the present disclosure;

FIG. 3 schematically illustrates a cross-sectional view of a nozzle and a home port according to an embodiment of the present disclosure;

FIG. 4 schematically illustrates a top view of a home port according to an embodiment of the present disclosure;

FIG. 5 is an exemplary diagram illustrating a method for cleaning a nozzle in a home port according to an embodiment of the present disclosure;

FIG. 6 is an exemplary diagram illustrating a method for cleaning a nozzle in a home port according to an embodiment of the present disclosure; and

FIG. 7 is an exemplary diagram illustrating a method for cleaning a nozzle in a home port according to an embodiment of the present disclosure.

### DETAILED DESCRIPTION

Hereinafter, preferred embodiments of the present disclosure will be described in detail so that those skilled in the art may easily practice the present disclosure with reference to the accompanying drawings. However, the embodiments of the present disclosure may be modified in various different forms, and the scope of the present disclosure is not limited to the embodiments described below.

In addition, the embodiments of the present disclosure are provided to more completely explain the present disclosure to those of ordinary skill in the art.

In the drawings, the shapes and sizes of elements may be exaggerated for clarity.

In describing preferred embodiments of the present disclosure in detail, when it is determined that a detailed description of a related known function or configuration may unnecessarily obscure the subject matter of the present disclosure, the detailed description will be omitted. The terms described below are terms defined in consideration of the functions in the present disclosure, which may vary depending on the intention or custom of the user or operator. Therefore, the definition should be based on the contents throughout the present specification. The terminology used in the detailed description is only for describing the embodiments of the present disclosure and should in no way be limiting. Unless explicitly stated otherwise, singular forms of expression include plural forms.

In addition, the same reference numerals are used throughout the drawings for parts having similar functions and actions. In addition, in the present specification, terms such as ‘on,’ ‘upper portion,’ ‘upper surface,’ ‘below,’ ‘lower portion,’ ‘lower surface,’ ‘side surface,’ and the like are based on the drawings, and may be changed depending on the direction in which components are actually disposed.

In addition, throughout the specification, when a part is said to be ‘connected’ to another part, this is not only when it is ‘directly connected,’ but also when it is ‘indirectly connected’ with other components therebetween. Further, ‘including’ a certain component means that other components may be further included, rather than excluding other components unless otherwise stated.

Hereinafter, the present disclosure will be described in detail through each embodiment or example of the present disclosure. It should be noted that each embodiment or example described in the present specification is not limited to a single embodiment or example, and combinations with other embodiments or examples are also possible. Therefore, the citation of claims in the scope of the patent claims is only an example of an embodiment, and the technical idea of the present disclosure should not be interpreted only as a combination with the cited claims, and combinations with various claims are also included in the scope of the technical idea of the present disclosure.

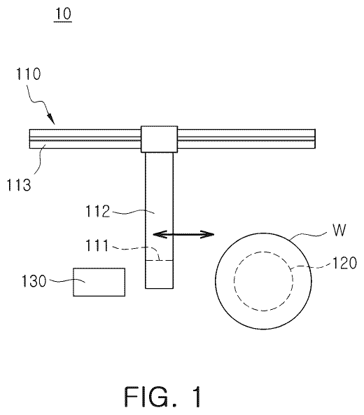

FIG. 1 schematically illustrates an apparatus for processing a substrate according to an embodiment of the present disclosure. An apparatus for processing a substrate 10 may include a liquid supply unit 110, a support unit 120, and a home port 130.

The liquid supply unit 110 may supply a processing liquid onto a surface of a substrate W. The processing liquid may be, for example, a developing liquid.

The liquid supply unit 110 may include a nozzle 111, a nozzle support member 112, and a nozzle moving member 113.

The support unit 120 may support the substrate W. The support unit 120 may rotate the supported substrate W. For example, the support unit 120 may include a chuck supporting and rotating the substrate W.

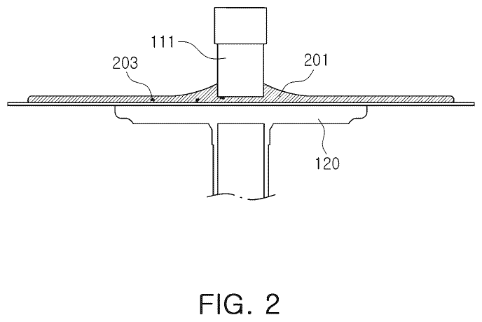

As illustrated in FIG. 2, the nozzle 111 may eject a processing liquid onto the substrate (W) supported by the support unit 120. The processing liquid may be, for example, a developer.

In an embodiment, the nozzle 111 may be a contact nozzle forming a developer puddle on the surface of the substrate (W). The nozzle 111 may supply a developer to the substrate (W) while maintaining a preset distance from the substrate (W).

In this case, contamination of the nozzle 111 may occur due to a photosensitive solution residue 203 remaining on the substrate (W).

Referring to FIG. 1 again, the nozzle support member 112 may support the nozzle 111. The nozzle 111 may be installed on a lower surface of one end of the nozzle support member 112.

A nozzle 111 may be installed on one end of the nozzle support member 112, and a nozzle moving member 113 may be connected to the other end of the nozzle support member 112.

The nozzle moving member 113 may include a rail and a driving mechanism. The nozzle 111 may be moved by the nozzle moving member 113 while being supported by the nozzle support member 112.

A home port 130 may be located to be spaced apart from the support unit. The home port 130 may provide a place in which the nozzle 111 is held between operations in which the nozzle 111 processes multiple substrates W. For example, the nozzle moving member 113 may move the nozzle 111 upwardly of the substrate (W) supported by the support unit 120. When developer supply processing in which the nozzle 111 supplies a developer to the substrate (W), is completed, the nozzle moving member 113 may move the nozzle 111 to the home port 130.

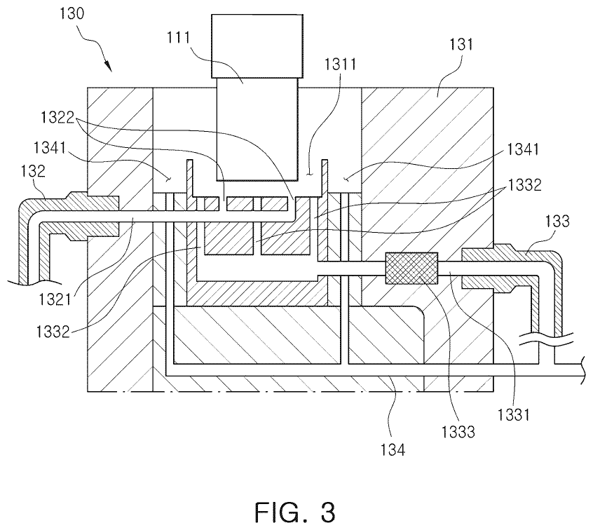

Hereinafter, a home port 130 of an apparatus for processing a substrate 10 according to an embodiment of the present disclosure will be described in detail with reference to FIGS. 3 to 7.

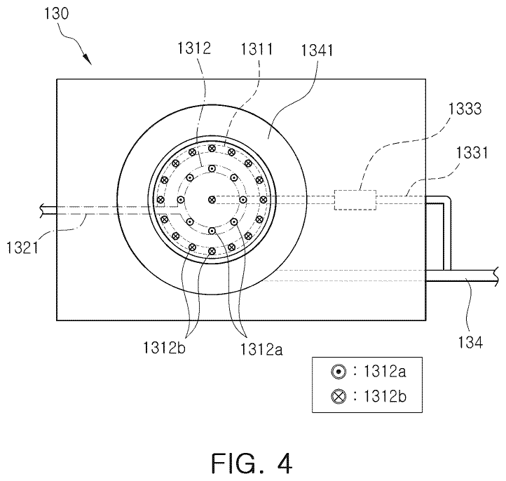

FIG. 3 is a side cross-sectional view of a home port 130 and a nozzle 111 received in the home port 130 according to an embodiment of the present disclosure. In addition, FIG. 4 is a top view of a home port 130 according to an embodiment of the present disclosure.

Referring to FIGS. 3 and 4 together, the home port 130 may include a housing 131, a cleaning liquid supply unit 132, a suction unit 133, and a drain unit 134.

The housing 131 may include a receiving space 1311 receiving a lower portion of the nozzle 111.

The housing 131 may further include a bottom member 1312 forming a bottom of the receiving space 1311 facing a lower surface of the nozzle 111 received in the receiving space 1311. The bottom member 1312 may include a plurality of bottom holes 1312a and 1312b for a fluid to pass therethrough.

The cleaning liquid supply unit 132 may supply a cleaning liquid to the receiving space 1311. The cleaning liquid may be used to clean the nozzle 111 contaminated with a photoresist solution residue. The cleaning liquid may be, for example, deionized water.

The cleaning liquid supply unit 132 may include a cleaning liquid supply path 1321 and a plurality of cleaning liquid distribution paths 1322 branched from the cleaning liquid supply path 1321.

The cleaning liquid supply path 1321 may be installed inside the housing 131, and may supply a cleaning liquid toward the receiving space 1311.

A plurality of cleaning liquid distribution paths 1322 may be installed inside the housing 131, and may be connected to one end of the cleaning liquid supply path 1321. The plurality of cleaning liquid distribution paths 1322 may form paths branched into a plurality of paths from one end of the cleaning liquid supply path 1321.

A plurality of bottom holes 1312a and 1312b formed in the bottom member 1312 of the housing 131 may include a plurality of first bottom holes 1312a through which a cleaning liquid supplied to the interior of the receiving space 1311 through the cleaning liquid supply unit 132 passes.

The plurality of first bottom holes 1312a may be connected to one end of the plurality of cleaning liquid distribution paths 1322.

That is, the cleaning liquid may be supplied to a plurality of cleaning liquid distribution paths 1322 through the cleaning liquid supply path 1321, and may be supplied to the interior of the receiving space 1311 by being branched into a plurality of paths by the plurality of cleaning liquid distribution paths 1322 and passing through the plurality of first bottom holes 1312a.

The suction unit 133 may suction a cleaning liquid or air from the receiving space 1311.

The suction unit 133 may include a suction path 1331, a plurality of suction distribution paths 1332, and an ejector 1333.

The suction path 1331 may be installed inside the housing 131, and may suction a cleaning liquid or air from the interior of the receiving space 1311.

A plurality of suction distribution paths 1332 may be installed inside the housing 131, and may be connected to one end of the suction path 1331. The plurality of suction distribution paths 1332 may form paths branched into a plurality of paths from one end of the suction path 1331.

An ejector 1333 may be installed in the suction path 1331. The ejector 1333 may control pressure within the suction path 1331. For example, the ejector 1333 may suction a cleaning liquid or air present within the receiving space 1311 by lowering the pressure within the suction path 1331.

The plurality of bottom holes 1312a and 1312b formed in the bottom member 1312 of the housing 131 may include a plurality of second bottom holes 1312b through which a cleaning liquid or air suctioned from the receiving space 1311 through the suction unit 133 passes.

The plurality of second bottom holes 1312b may be connected to one end of a plurality of suction distribution paths 1332.

That is, the cleaning liquid or air present within the receiving space 1311 may pass through the plurality of second bottom holes 1312b and be suctioned into the plurality of suction distribution paths 1332, and can be transferred from the plurality of suction distribution paths 1332 to the suction path 1331.

In an embodiment, the suction path 1331 may be disposed at a lower height than the cleaning liquid supply path 1321. By disposing the suction path 1331 to be lower than the cleaning liquid supply path 1321, interference between the two paths may be avoided, and the cleaning liquid supply and suction may be performed more smoothly.

The drain unit 134 may drain a cleaning liquid having overflowed from the receiving space 1311 and a cleaning liquid suctioned through the suction unit 133 to the outside of the housing 131.

The drain unit 134 may include an overflow space 1341. The overflow space 1341 may receive a cleaning liquid having overflowed from the receiving space 1311. The cleaning liquid having overflowed from the receiving space 1311 may be drained from the overflow space 1341 to the outside of the housing 1311 through a path of the drain unit 134.

The path of the drain unit 134 may be connected to the suction unit 133. The cleaning liquid suctioned through the suction unit 133 from the receiving space 1311 may be drained to the outside of the housing 131 through the path of the drain unit 134.

The nozzle 111 is a contact nozzle forming a developer puddle on a surface of the substrate (W), and the cleaning liquid supplied from the home port 130 may be used to remove a photosensitive solution residue attached to a lower portion of the nozzle 111 from the substrate (W).

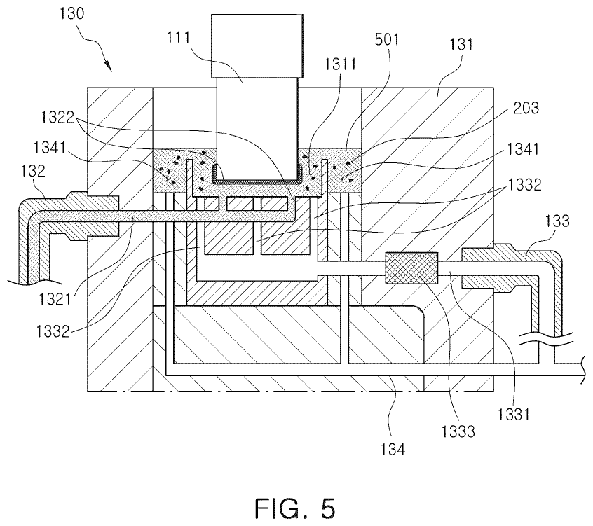

FIGS. 5 to 7 are exemplary diagrams illustrating a method for cleaning a nozzle in a home port according to an embodiment of the present disclosure.

As illustrated in FIG. 5, a cleaning liquid supply unit 132 may supply a cleaning liquid 501 into the interior of a receiving space 1311.

Specifically, the cleaning liquid 501 may be supplied to a plurality of cleaning liquid distribution paths 1322 through a cleaning liquid supply path 1321, and may be branched into a plurality of paths by the plurality of cleaning liquid distribution paths 1322 and supplied to the interior of the receiving space 1311.

The cleaning liquid supply unit 132 may separate the photosensitive solution residue 203 from the nozzle 111 by using the pressure of the cleaning liquid supplied to the interior of the receiving space 1311.

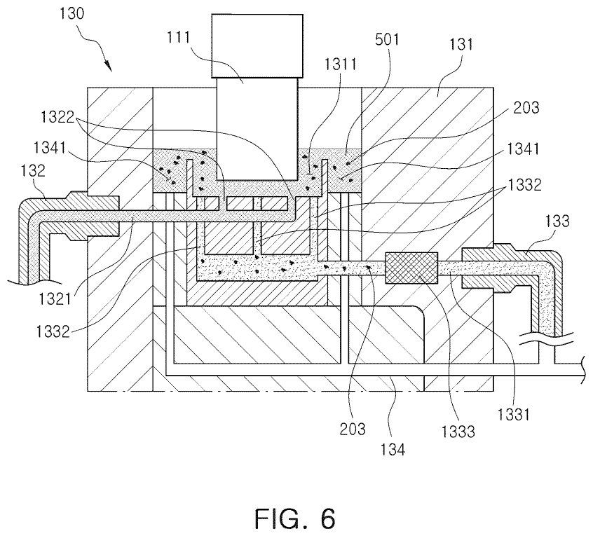

As illustrated in FIG. 6, the photosensitive solution residue 203 separated from the nozzle 111 may be located inside the receiving space 1311 together with the cleaning liquid 501, or may overflow into the overflow space 1341.

The suction unit 133 may suction the cleaning liquid 501 and the photosensitive solution residue 203 located in the receiving space 1311 by reducing the pressure within the suction path 1331 using the ejector 1333. Thereby, the suction unit 133 may remove the cleaning liquid and photosensitive solution residue from the receiving space 1311.

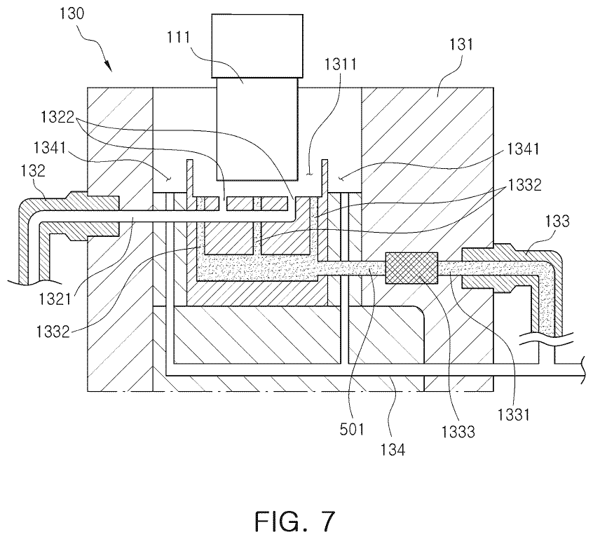

As illustrated in FIG. 7, the suction unit 133 may suction all of the cleaning liquid 501 within the receiving space 1311. After the cleaning liquid 501 is removed from the interior of the receiving space 1311, the suction unit 133 may dry the nozzle 111 by suctioning air from the interior of the receiving space 1311 using the ejector 1333.

According to the home port of the present disclosure, it is possible to efficiently perform cleaning and drying processing of the nozzle.

In some embodiments disclosed in this application, it should be understood that the disclosed devices and methods may be implemented in other ways. For example, the device embodiments described above are merely exemplary, and for example, the division of the units is merely a kind of logical functional division, and other division methods may exist in actual implementation, and for example, a plurality of units or assemblies may be combined or integrated into another system. On the other hand, the coupling or direct coupling or communication connection between the things shown or discussed may be an indirect coupling or communication connection via some interface, device or unit, and may be in electrical, mechanical or other form.

The units described above as separate components may be physically separate, and the components represented as units may or may not be physical units, i.e., located in one location or distributed across multiple network units. Depending on actual needs, some or all of these units may be selected to achieve the objectives of the present embodiment.

That is, each functional unit in each embodiment of the present application may be integrated into one processing unit, each unit may exist alone, or two or more units may be integrated into one unit.

As set forth above, according to the present disclosure, a home port and an apparatus for processing a substrate including the same, which can reduce a defect rate of a process by efficiently performing cleaning and drying processing of a nozzle for processing a substrate, may be provided.

In an embodiment of the present disclosure, a home port and an apparatus for processing a substrate including the same, which can separate contaminants from a nozzle by supplying a cleaning liquid to a receiving space receiving a lower portion of a nozzle, suction the separated contaminants together with the cleaning liquid, and then perform drying processing of the nozzle all at once, may be provided.

While exemplary embodiments have been shown and described above, it will be apparent to those skilled in the art that modifications and variations could be made without departing from the scope of the present invention as defined by the appended claims.

What is claimed is:

1. A home port, comprising:
a housing including a receiving space for receiving a lower portion of a nozzle;
a cleaning liquid supply unit for supplying a cleaning liquid for cleaning the nozzle to the receiving space;
a suction unit for suctioning the cleaning liquid or air from the receiving space; and
a drain unit for draining a cleaning liquid having overflowed from the receiving space and a cleaning liquid suctioned through the suction unit to the outside of the housing.

2. The home port of claim 1, wherein the housing further comprises
a bottom member forming a bottom of the receiving space facing a lower surface of the nozzle received in the receiving space,
wherein the bottom member includes a plurality of bottom holes through which a fluid passes.

3. The home port of claim 2, wherein the cleaning liquid supply unit comprises
a cleaning liquid supply path installed inside the housing, and supplying the cleaning liquid toward the receiving space; and
a plurality of cleaning liquid distribution paths connected to one end of the cleaning liquid supply path, and branched into a plurality of paths.

4. The home port of claim 3, wherein the plurality of bottom holes include a plurality of first bottom holes through which the cleaning liquid supplied to the interior of the receiving space through the cleaning liquid supply unit passes,
wherein the plurality of first bottom holes are connected to one end of the plurality of cleaning liquid distribution paths.

5. The home port of claim 3, wherein the suction unit comprises
a suction path installed inside the housing, and suctioning the cleaning liquid or the air from the interior of the receiving space;
a plurality of suction distribution paths connected to one end of the suction path, and branched into a plurality of paths; and
an ejector installed in the suction path, and controlling pressure within the suction path.

6. The home port of claim 3, wherein the plurality of bottom holes include a plurality of second bottom holes through which the cleaning liquid or the air suctioned from the receiving space through the suction unit passes,
wherein the plurality of second bottom holes are connected to one end of the plurality of suction distribution paths.

7. The home port of claim 5, wherein the suction path is disposed at a lower height than the cleaning liquid supply path.

8. The home port of claim 5, wherein the nozzle is a contact nozzle forming a developer puddle on a surface of the substrate, and
the cleaning liquid is for removing a photoresist solution residue attached to a lower portion of the nozzle from the substrate.

9. The home port of claim 8, wherein the cleaning liquid supply unit separates the photosensitive solution residue from the nozzle by using the pressure of the cleaning liquid supplied to the interior of the receiving space.

10. The home port of claim 9, wherein the suction unit removes the cleaning liquid and the photosensitive solution residue located in the receiving space by reducing the pressure within the suction path using the ejector.

11. The home port of claim 10, wherein the suction unit dries the nozzle by suctioning air within the receiving space using the ejector after the cleaning liquid within the receiving space is removed.

12. A home port, comprising:
a housing including a receiving space for receiving a lower portion of a nozzle;
a cleaning liquid supply path installed inside the housing and supplying a cleaning liquid to the receiving space;
a suction path installed inside the housing and suctioning the cleaning liquid from the receiving space; and
an ejector installed in the suction path, and controlling pressure within the suction path.

13. The home port of claim 12, wherein the suction path is disposed at a lower height than the cleaning liquid supply path.

14. The home port of claim 12, wherein the nozzle is a contact nozzle forming a developer puddle on a surface of a substrate, and
the cleaning liquid is for removing a photoresist solution residue attached to a lower portion of the nozzle from the substrate.

15. The home port of claim 14, wherein the photosensitive solution residue is separated from the nozzle by the pressure of the cleaning liquid supplied to the interior of the receiving space through the cleaning liquid supply path.

16. The home port of claim 15, wherein the ejector removes the cleaning liquid and the photosensitive solution residue located in the receiving space by reducing the pressure within the suction path.

17. The home port of claim 15, wherein the ejector dries the nozzle by suctioning air within the receiving space after the cleaning liquid within the receiving space is removed.

18. In an apparatus for processing a substrate, the apparatus, the apparatus including:
a support unit for supporting a substate;
a liquid supply unit including a nozzle for discharging a processing liquid onto a substrate supported by the support unit; and
a home port located to be spaced apart from the support unit, and in which the nozzle is held,
wherein the home port includes
a housing including a receiving space in which a portion of the nozzle is received;
a cleaning liquid supply unit for supplying a cleaning liquid for cleaning the nozzle to the receiving space;
a suction unit for suctioning the cleaning liquid or air from the receiving space; and
a drain unit for draining a cleaning liquid having overflowed from the receiving space and a cleaning liquid suctioned through the suction unit to the outside of the housing.

19. The apparatus for processing a substrate of claim 18, wherein the cleaning liquid supply unit comprises:
a cleaning liquid supply path installed inside the housing, and supplying the cleaning liquid toward the receiving space; and
a plurality of cleaning liquid distribution paths connected to one end of the cleaning liquid supply path, and branched into a plurality of paths.

20. The apparatus for processing a substrate of claim 18, wherein the suction unit comprises:
a suction path installed inside the housing, and suctioning the cleaning liquid or the air from the interior of the receiving space;
a plurality of suction distribution paths connected to one end of the suction path, and branched into a plurality of paths; and
an ejector installed in the suction path, and controlling pressure within the suction path.
